(19) United States
(12) Patent Application Publication
(10) Pub. No.: US 2020/0020724 A1
(43) Pub. Date: Jan. 16, 2020

(54) OPTOELECTRONIC DEVICES

(71) Applicant: FLEXENABLE LIMITED, Cambridge (GB)

(72) Inventor: Burag YAGLIOGLU, Cambridge (GB)

(73) Assignee: FLEXENABLE LIMITED, Cambridge (GB)

(21) Appl. No.: 16/505,895

(22) Filed: Jul. 9, 2019

(30) Foreign Application Priority Data
Jul. 10, 2018 (GB) 1811274.8

(51) Int. Cl. H01L 27/12; G02F 1/1368; G02F 1/1343; H01L 27/28; H01L 51/05; G02F 1/1362

(52) U.S. Cl. CPC H01L 27/1255; G02F 1/1368; G02F 1/134309; H01L 27/283; G02F 2201/123; G02F 1/136213; G02F 2001/13685; G02F 2001/134372; H01L 51/0541

(57) ABSTRACT

A device comprising: a stack of layers supported on a support film and defining an array of pixel electrodes and electrical circuitry via which each pixel electrode is independently addressable via conductors outside of the array of pixel electrodes; and transmissive conductors supported on said support film at a first conductor level below said stack of layers in the regions of said pixel electrodes; wherein said conductors are light-transmissive and are connected within the first conductor level to a conductor outside the array of pixel electrodes; wherein said transmissive conductors exhibit a substantially higher transmittance for some wavelengths in the visible spectrum than for other wavelengths in the visible spectrum.

Some optoelectronic devices comprise an array of independently addressable pixel electrodes, and increasing the capacitive coupling between each pixel electrode and other conductor elements can be advantageous.

One conventional technique comprises defining storage capacitors within a stack of layers that defines the electrical circuitry via which each pixel electrode is independently addressable.

The inventor for the present application has conducted research around developing an alternative technique for achieving good capacitive coupling with the pixel electrodes.

There is hereby provided a device comprising: a stack of layers supported on a support film and defining an array of pixel electrodes and electrical circuitry via which each pixel electrode is independently addressable via conductors outside of the array of pixel electrodes; and transmissive conductors supported on said support film at a first conductor level below said stack of layers in the regions of said pixel electrodes; wherein said conductors are light-transmissive and are connected within the first conductor level to a conductor outside the array of pixel electrodes.

According to one embodiment, said conductor outside the array of pixel electrodes is connected by conductor material to a second conductor level within said stack.

According to one embodiment, said transmissive conductors exhibit substantially the same transmittance for all wavelengths between 400 and 800 nm.

According to one embodiment, said transmissive conductors exhibit a substantially higher transmittance for some wavelengths in the visible spectrum than for other wavelengths in the visible spectrum.

According to one embodiment, said transmissive conductors comprise: at least one transmissive conductor that exhibits a primary transmission peak in the red region; at least one transmissive conductor that exhibit a primary transmission peak in the blue region; and at least one transmissive conductor that exhibits a primary transmission peak in the blue region.

According to one embodiment, said stack of layers includes a source-drain conductor pattern defining an array of source conductors and an array of drain conductors; and semiconductor channel material connecting said source and drain conductors in channel regions where the source and drain conductors are in closest proximity; and wherein said device further comprises non-transmissive conductors in said channel regions at said first conductor level, wherein the non-transmissive conductors are substantially non-transmissive over the visible spectrum.

According to one embodiment, the non-transmissive conductors are isolated from the transmissive conductors within the first conductor level.

According to one embodiment, the non-transmissive conductors and transmissive conductors are in contact with each other within the first conductor level.

According to one embodiment, said transmissive conductors comprise one or more conductive metal oxide materials, and said non-transmissive conductors comprise one or more metallic materials.

According to one embodiment, said non-transmissive conductors comprise one or more metallic materials, and define periodic nanohole arrays.

There is also hereby provided a method of operating a device as described above, comprising applying to the transmissive conductors one or more voltages that facilitate capacitive coupling of the transmissive conductors with the pixel electrodes.

According to one embodiment, the method comprises: applying to all transmissive conductors a common voltage that facilitates capacitive coupling of the transmissive conductors with the pixel electrodes.

There is also hereby provided a method of operating a device as described above, comprising using the transmissive conductors to increase the storage capacitance of the pixel electrodes.

Embodiments of the present invention are described hereunder, by way of example only, with reference to the accompanying drawings, in which:—

FIG. 1 is a schematic cross-sectional illustration of an embodiment of the present invention;

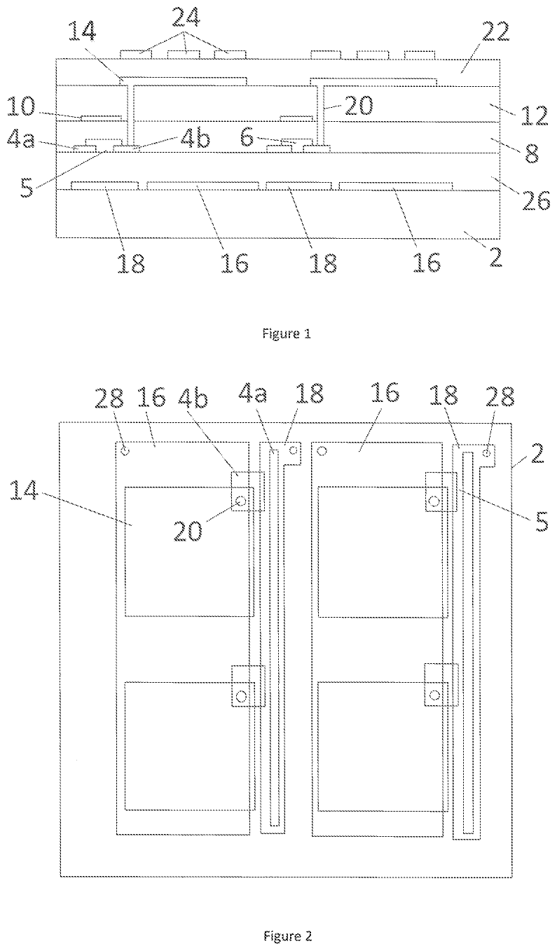

FIG. 2 is a schematic plan illustration of an embodiment of the present invention; and

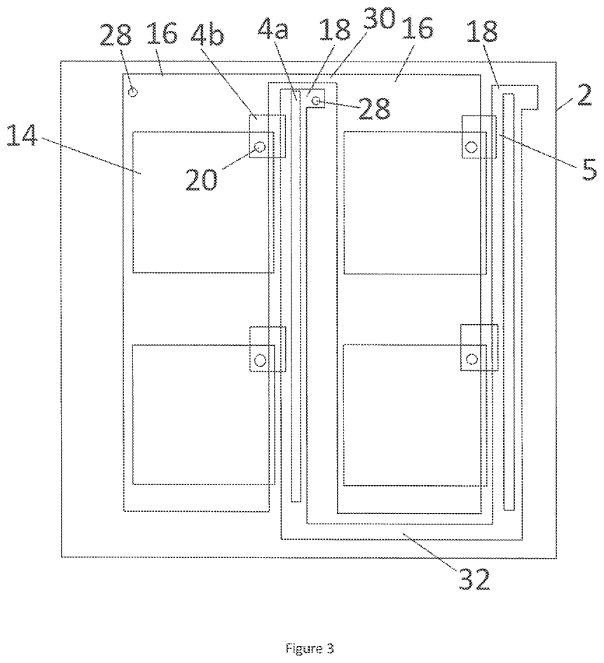

FIG. 3 is a schematic plan illustration of a variation of the embodiment shown in FIG. 2.

For conciseness and clarity, an embodiment is described below for the example of a device comprising an array of only 4 pixel electrodes, but the same techniques is equally applicable to devices comprising arrays of very large numbers of pixel electrodes.

The embodiment described below is for the example of a top-gate transistor array for a fringe-field switching (FFS) LCD devices, but the techniques are also applicable to other types of transistor arrays for FFS-LCD devices, and to transistor arrays for other types of devices including other types of LCD devices.

For the purposes of this document, the term “source conductor” refers to a conductor in electrical series between drive circuitry (such as a driver chip) and the semiconductor channel, and the term “drain conductor” refers to a conductor in electrical series with the drive circuitry (e.g. driver chip) via the semiconductor channel.

The semiconductor channel material may comprise one or more organic semiconductor materials (such as e.g. organic polymer semiconductors), and/or one or more inorganic semiconductor materials.

FIGS. 1 and 2 show an example of a control component for a LCD device, according to an embodiment of the invention.

The control component comprises a stack of patterned conductor, semiconductor and insulator layers formed in situ on a support element 2. For example, the support element 2 comprises a self-supporting, flexible, plastic film as its primary component. The stack defines an array of pixel electrodes 14, and electrical circuitry for independently addressing each of the pixel electrodes 14 via conductors outside the array of pixel electrodes 14. The electrical circuitry includes a source-drain conductor pattern at a first conductor level; an array of gate conductors 10 (not shown in FIG. 2) at second conductor level; the array of pixel electrodes 14 at a third conductor level; and a patterned common conductor 24 at a fourth conductor level. Between each pair of adjacent levels are one or more insulator/dielectric layers, but there can be conductive connections between conductor elements in different conductor levels via via-holes 20 formed through the insulator/dielectric layer(s).

In this example, the electrical circuitry defined by the stack is spread over 4 conductor levels, but the techniques described below are equally applicable to a control component for FFS-LCD devices (or control components for other types of LCD devices or other optoelectronic devices) where the electrical circuitry is spread over a smaller or larger number of conductor levels. For example, the techniques described below are equally applicable to a control component for a FFS-LCD device, in which the electrical circuitry defined by the stack is spread over two levels, with the source-drain conductor pattern and array of pixel electrodes at one conductor level, and the gate conductors and patterned common conductor at a second conductor level.

The source-drain conductor pattern defines at least (i) an array of source conductors 4a each associated with a respective column of transistors and extending beyond an edge of the array of pixel electrodes for connection to a respective terminal of a driver chip (not shown), and (ii) an array of drain conductors 4b, each drain conductor associated with a respective transistor. Each source conductor 4a includes an addressing line that extends beyond an edge of the array of pixel electrodes for connection to a respective terminal of a driver chip.

According to one variation, the source and drain conductors comprise interdigitated fingers in the channel regions 5 where the source and drain conductors are in closest proximity, in order to increase the width of the semiconductor channels between the source and drain conductors.

The stack of layers includes a patterned layer of semiconductor channel material formed in situ on the workpiece. The patterned layer of semiconductor channel material provides an array of isolated islands 6 of semiconductor channel material, each island 6 providing the semiconductor channel for a respective transistor of the array. The semiconductor channel material may be in contact with the source and drain conductors via one or more layers that improve charge transfer between the source-drain conductor pattern and the semiconductor channel material, such as e.g. a self-assembled monolayer of a suitable organic material.

The gate conductor pattern at the second conductor level defines an array of gate conductors 10, each capacitively coupled via a gate dielectric layer (or stack of gate dielectric layers) 8 to the semiconductor channels 6 of a respective row of transistors. Each gate conductor 10 is associated with a respective row of transistors and each extends beyond an edge of the pixel electrode array for electrical connection to a respective terminal of a driver chip. Each transistor is associated with a unique combination of gate and source conductors, whereby each pixel electrode 14 can be addressed independently of all other pixel electrodes 14, via portions of the source and gate conductors outside of the pixel electrode array.

Each pixel electrode 14 at the 3^{rd} conductor level extends down to a respective drain conductor at the 1^{st} conductor level via via-holes 20 formed through the gate dielectric layer(s) 8 and one or more insulator/dielectric layers 12 between the 2^{nd} and 3^{rd} conductor levels.

The patterned common conductor 24 at the 4^{th} conductor level are capacitively coupled to the pixel electrodes 14 via one or more insulator/dielectric layers between the 3^{rd} and 4^{th} conductor levels. The operation of the FFS-LCD device involves controlling a potential difference between a pixel electrode 14 and the COM conductor 24.

This example embodiment comprises further conductors 16, 18 also supported by the support element 2, but at another conductor level (hereafter referred to as the 0^{th} conductor level) below the above-described stack of layers. A planarisation layer 26 (e.g. SU-8 layer having a thickness of about 2 microns) is formed over these extra conductors and provides a planarised surface for the formation of the source-drain conductor pattern described above.

These conductors 16, 18 at the 0^{th} conductor level comprise a first set of non-transmissive conductors 18 in at least the channel regions 5 mentioned above. In this example, these non-transmissive conductors 18 take the form of a set of non-transmissive parallel conductor lines 18, each line 18 passing under the channel regions 5 for a respective column of transistors. Each non-transmissive conductor line 18 extends to a location outside the array of pixel electrodes 4, where they are connected to one or more conductors at the first conductor level via one or more via-holes 28 through the planarisation layer 26. This facilitates the application of a voltage to the non-transmissive conductors 18.

In this example, the non-transmissive conductor lines 18 are solid metal lines without any patterning within the footprint of the metal lines. The non-transmissive conductor lines 18 are of a thickness and width sufficient to adequately shield the semiconductor channels 6 from light from the direction of the support element 2. The non-transmissive conductor lines 18 may also be used to tune the threshold voltage of the transistors by applying a bias voltage to the conductor lines 18 via the conductors mentioned above outside the area of the pixel electrode array at the first conductor level. The non-transmissive conductor lines may be substantially non-transmissive/opaque over substantially the whole visible spectrum.

The extra conductors at the 0^{th} conductor level additionally comprise transmissive conductors 16 in at least part of the pixel electrode regions 5 mentioned above. In this example, these transmissive conductors 16 take the form of a second set of parallel conductor lines 16 (parallel with the non-transmissive conductor lines 16 to create a pattern of alternating transmissive and non-transmissive conductor lines). Each transmissive conductor line 16 passes under the pixel electrode regions 14 for a respective column of transistors; and each transmissive conductor line 16 also extends to a location outside the array of pixel electrodes, where they are connected to one or more conductors at the first conductor level via one or more via-holes 28 through the planarisation layer 26. This facilitates the application of a voltage to the transmissive conductor lines 16.

In this example, the transmissive conductor lines 16 are isolated from the non-transmissive conductor lines 18 within the 0^{th} conductor level, to allow the two sets of conductor lines to be held at different electric potentials. For example, the non-transmissive conductor lines 18 may be held at one or more electric potentials designed to achieve the desired tuning of the threshold voltage of the transistors, while the transmissive conductor lines 16 may all be held at a common electric potential designed to achieve a desired level of capacitive coupling between the pixel electrodes 14 and the transmissive conductors 16 via the dielectric layers 26, 8, 12.

According to one variation illustrated in FIG. 3: all the non-transmissive conductor lines 18 are conductively connected to one another within the 0^{th} conductor level through a conductor busbar 32 in a region outside one edge of the pixel electrode array; and all the transmissive conductor lines 16 are conductively connected to one another within the 0^{th} conductor level through a conductor busbar 30 in a region outside an opposite edge of the pixel electrode array. All of the transmissive conductor lines 16 are connected to a common conductor at the first conductor level via a single via-hole 28 (or a plurality of common via-holes 28) through the planarisation layer 26. This facilitates the application of a common voltage to all transmissive conductor lines 16. Similarly, all of the non-transmissive conductor lines 18 are connected to a common conductor at the first conductor level via a single via-hole 28 (or a plurality of common via-holes 28) through the planarisation layer 26.

In one example, the transmissive conductor lines 16 are made from a conductive metal oxide material such as indium-tin-oxide (ITO), and exhibit substantially the same transmittance across substantially the whole of the visible spectrum, whereby e.g. a backlight source of white light appears white when viewed through the transmissive conductors 16.

In another example, the transmissive conductor lines 16 are made from a metallic material but define a periodic array of nanoholes (e.g. holes having a radius of about 100 nm) in at least the parts of the transmissive conductor lines 116 underlying the pixel electrodes 14. These nanoholes are filled with the dielectric material of the after-deposited planarisation layer 26, and function as plasmonic colour filters with a primary transmission peak within the visible spectrum at a wavelength dependent on the pitch of the nanohole array. In one example, the pitch of the nanohole arrays is different for different pixel regions, such that the transmissive conductors 18 provide an array of colour filters: e.g. a first set of filters having a primary transmission peak in the red region of the visible spectrum for a first set of the pixel electrodes; a second set of filters having a primary transmission peak in the green region for a second set of the pixel electrodes; and a third set of filters having a primary transmission peak in the blue region for a third set of the pixel electrodes.

In one example, the non-transmissive and transmissive conductors 16, 18 both form part of a continuous layer of metallic material extending continuously over the whole area of the pixel electrode array, with nanohole patterning of the continuous layer in the pixel electrode regions but no nanohole patterning in the channel regions 5.

The control component described above may be incorporated into a FFS-LCD cell by: forming an alignment layer (e.g. rubbed polyimide layer) over the 4^{th} conductor level; and containing LC material between the resulting component and a counter component also provided with the same kind of alignment layer. Spacers may be used to better maintain a uniform thickness of liquid crystal material between the two components across all pixels.

An example embodiment of the invention is described above in the context of a FFS-LCD display device, but the same technique is also applicable to other types of display devices (such as in-plane switching (IPS) LCD devices in which the pixel electrodes 14 and the COM conductors 24 are at the same conductor level) and to the production of other types of devices comprising an array of pixel electrodes such as sensor devices.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A device comprising: a stack of layers supported on a support film and defining an array of pixel electrodes and electrical circuitry via which each pixel electrode is independently addressable via conductors outside of the array of pixel electrodes; and transmissive conductors supported on said support film at a first conductor level below said stack of layers in the regions of said pixel electrodes; wherein said conductors are light-transmissive and are connected within the first conductor level to a conductor outside the array of pixel electrodes.

2. The device according to claim 1, wherein said conductor outside the array of pixel electrodes is connected by conductor material to a second conductor level within said stack.

3. The device according to claim 1, wherein said transmissive conductors exhibit substantially the same transmittance for all wavelengths between 400 and 800 nm.

4. The device according to claim 1, wherein said transmissive conductors exhibit a substantially higher transmittance for some wavelengths in the visible spectrum than for other wavelengths in the visible spectrum.

5. The device according to claim 4, wherein said transmissive conductors comprise: at least one transmissive conductor that exhibits a primary transmission peak in the red region; at least one transmissive conductor that exhibit a primary transmission peak in the blue region; and at least one transmissive conductor that exhibits a primary transmission peak in the blue region.

6. The device according to claim 1, wherein said stack of layers includes a source-drain conductor pattern defining an array of source conductors and an array of drain conductors; and semiconductor channel material connecting said source and drain conductors in channel regions where the source and drain conductors are in closest proximity; and wherein said device further comprises non-transmissive conductors in said channel regions at said first conductor level, wherein the non-transmissive conductors are substantially non-transmissive over the visible spectrum.

7. The device according to claim 6, wherein the non-transmissive conductors are isolated from the transmissive conductors within the first conductor level.

8. The device according to claim 6, wherein the non-transmissive conductors and transmissive conductors are in contact with each other within the first conductor level.

9. The device according to claim 6, wherein said transmissive conductors comprise one or more conductive metal oxide materials, and said non-transmissive conductors comprise one or more metallic materials.

10. The device according to claim 1, wherein said non-transmissive conductors comprise one or more metallic materials, and define periodic nanohole arrays.

11. A method of operating a device according to claim 1, comprising applying to the transmissive conductors one or more voltages that facilitate capacitive coupling of the transmissive conductors with the pixel electrodes.

12. The method according to claim 11, comprising: applying to all transmissive conductors a common voltage that facilitates capacitive coupling of the transmissive conductors with the pixel electrodes.

13. A method of operating a device according to claim 1, comprising using the transmissive conductors to increase the storage capacitance of the pixel electrodes.
